(19) United States
(12) Patent Application Publication
(10) Pub. No.: US 2023/0088149 A1
(43) Pub. Date: Mar. 23, 2023

(54) METHOD OF FORMING THREE-DIMENSIONAL MEMORY DEVICE

(71) Applicant: MACRONIX International Co., Ltd., Hsinchu (TW)

(72) Inventors: Kuan-Yuan Shen, Hsinchu County (TW); Chia-Jung Chiu, Hsinchu County (TW)

(73) Assignee: MACRONIX International Co., Ltd., Hsinchu (TW)

(21) Appl. No.: 17/483,527

(22) Filed: Sep. 23, 2021

(51) Int. Cl. H01L 27/11582; H01L 27/11556; H01L 23/60

(52) U.S. Cl. CPC H01L 27/11582; H01L 27/11556; H01L 23/60

(57) ABSTRACT

Provided is a method of forming a three-dimensional (3D) memory device including: forming a discharging layer and a stack structure on a buffer layer; forming vertical channel structures in the stack structure; forming an opening in the stack structure, wherein the opening includes two first trenches extending along a X direction and two second trenches extending along a Y direction, and the two first trenches and the two second trenches are separated from each other; forming an insulating layer on a sidewall of the opening; removing the discharging layer exposed by the insulating layer to form a cavity connecting the two first trenches and the two second trenches, thereby forming a ring-shaped opening; performing a gate replacement process to replace sacrificial layers of the stack structure by conductive layers; and filling an isolating material in the ring-shaped opening to form an isolating ring structure.

### BACKGROUND OF THE INVENTION

### Field of the Invention

The present invention relates to a method of forming a semiconductor device, and more particularly to a method of forming a three-dimensional memory device.

### Description of Related Art

A non-volatile memory (such as a flash memory) is a memory widely used in personal computers and other electronic devices because it has an advantage that the stored data does not disappear after being powered off.

The 3D flash memory currently used in the industry includes a NOR flash memory and a NAND type flash memory. In addition, another type of 3D flash memory is an AND type flash memory, which can be applied to a multi-dimensional flash memory array with high integration and high area utilization, and has an advantage of fast operation speed. Therefore, the development of the 3D flash memory has gradually become the current trend.

### SUMMARY OF THE INVENTION

The invention provides a method of forming a three-dimensional (3D) memory device including following steps. A buffer layer having a first region and a second region is provided. The second region surrounds the first region. A stop layer and a stack structure including a plurality of dielectric layers and a plurality of sacrificial layers stacked alternately are formed on the buffer layer. The stack structure includes at least one vertical channel structure penetrating through the stack structure in the first region. A first opening is formed in the stack structure in the first region, and a second opening is formed in the stack structure in the second region. The second opening has a width greater than a width of the first opening. A dielectric material is formed to fill in the first and second openings. A first etching process is performed to remove at least a portion of the dielectric material on a bottom surface of the second opening to expose a portion of the stop layer, thereby forming a first dielectric layer in the first opening and forming a second dielectric layer on a sidewall of the second opening. A second etching process is performed to remove the stop layer exposed at the bottom surface of the second opening, thereby forming a cavity laterally extending below the stack structure, so that the cavity is connected to the second opening to form a closed ring.

The invention provides a three-dimensional (3D) memory device including following steps. A discharging layer and a stack structure including a plurality of dielectric layers and a plurality of sacrificial layers stacked alternately on a buffer layer. A plurality of vertical channel structures are formed in the stack structure. An opening is formed in the stack structure. The opening includes two first trenches extending along a X direction and two second trenches extending along a Y direction, and the two first trenches and the two second trenches are separated from each other. An insulating layer is formed on a sidewall of the opening. The insulating layer exposes the discharging layer at a bottom surface of the opening. The discharging layer exposed at the bottom surface of the opening is removed to form a cavity. The cavity extends below the stack structure to connect the two first trenches and the two second trenches, thereby forming a ring-shaped opening. A gate replacement process is performed to replace the plurality of sacrificial layers of the stack structure by a plurality of conductive layers. The plurality of conductive layers respectively surround the plurality of vertical channel structures to form a plurality of memory cells. An isolation material is filled in the ring-shaped opening to form an isolation ring structure.

Based on the above, in the present embodiment, a first opening and a second opening are formed in the array region and the isolation ring region simultaneously, so that the gate replacement process may be performed through the first and the second openings. The second opening may include an unclosed slit ring structure to prevent the discharge layer from being cut off by the second opening, thereby preventing the arcing effect. In addition, in the present embodiment, a subsequent etching process may be performed to remove the discharge layer exposed at the bottom surface of the second opening, thereby forming a cavity. The cavity may laterally penetrate through the unclosed slit ring structure to form a ring-shaped opening, thereby electrically or physically separating the discharge layer in the array region from the discharge layer in the outer region. In this case, the present embodiment can avoid the arcing effect while cutting the discharge layer, thereby improving the reliability of the 3D memory device.

### BRIEF DESCRIPTION OF THE DRAWINGS

The accompanying drawings are included to provide a further understanding of the invention, and are incorporated in and constitute a part of this specification. The drawings illustrate embodiments of the invention and, together with the description, serve to explain the principles of the invention.

FIG. 1 is a schematic cross-sectional view of a 3D memory device according to an embodiments of the invention.

FIG. 2A, FIG. 3A, and FIG. 4A are schematic cross-sectional views illustrating a vertical channel structure according to various embodiments of the invention.

FIG. 2B, FIG. 3B, and FIG. 4B are schematic plan views of FIG. 2A, FIG. 3A, and FIG. 4A, respectively.

FIG. 5 is a schematic plan view of a 3D memory device according to an embodiment of the invention.

FIG. 6A, FIG. 7A, FIG. 8A, FIG. 9A, FIG. 10A, FIG. 11A, FIG. 12A, and FIG. 13A are schematic cross-sectional views of a manufacturing process along a line A-A of FIG. 5.

FIG. 6B, FIG. 7B, FIG. 8B, FIG. 9B, FIG. 10B, FIG. 11B, FIG. 12B, and FIG. 13B are schematic cross-sectional views of a manufacturing process along a line B-B of FIG. 5.

FIG. 9C is a schematic plan view of a structure of FIG. 9A and FIG. 9B.

FIG. 14 is a schematic plan view of a 3D memory device according to another embodiment of the invention.

FIG. 15 is a schematic plan view of a 3D memory device according to alternative embodiments of the invention.

### DESCRIPTION OF THE EMBODIMENTS

The invention is more blanketly described with reference to the figures of the present embodiments. However, the invention can also be implemented in various different forms, and is not limited to the embodiments in the present specification. The thicknesses of the layers and regions in the figures are enlarged for clarity. The same or similar reference numerals represent the same or similar devices and are not repeated in the following paragraphs.

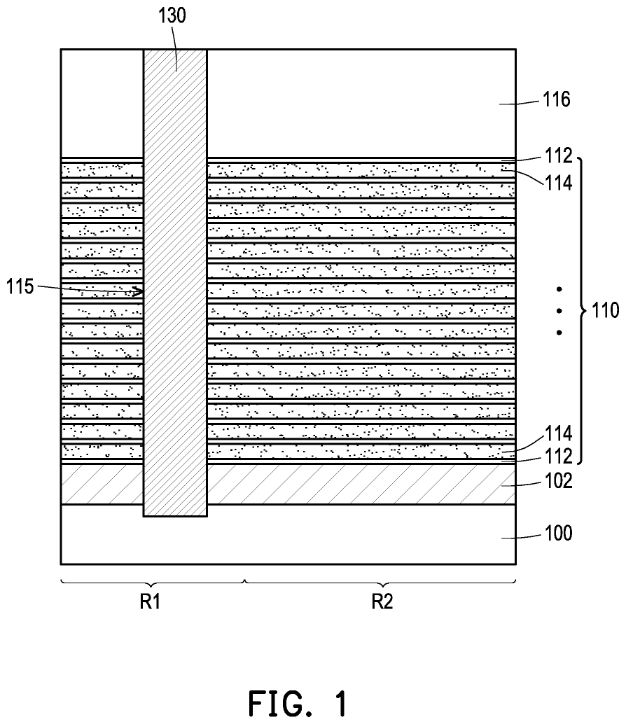

FIG. 1 is a schematic cross-sectional view of a 3D memory device according to an embodiments of the invention.

Referring to FIG. 1, in the embodiment of the present invention, a 3D memory device may include a buffer layer 100, a stack structure 110, a cap layer 116, and a vertical channel structure 130. In an embodiment, the buffer layer 100 includes a dielectric substrate. The dielectric substrate may be a dielectric layer formed on a silicon substrate, such as a silicon oxide layer. That is, there may be peripheral circuits under the buffer layer 100. In addition, the buffer layer 100 may include a first region R1 and a second region R2. In an embodiment, the first region R1 may be an array region, and the second region R2 may be an isolation ring region.

The stop layer 102 may be formed on the buffer layer 100. In an embodiment, a material of the stop layer 102 includes a conductive material. The conductive material may include a semiconductor material comprising polysilicon, III-V compound semiconductor, or a combination thereof. With an embodiment of the 3D memory device being a 3D NAND flash memory, the stop layer 102 may be used as a source line. With an embodiment of the 3D memory device being a 3D NOR flash memory, the stop layer 102 may be used as a dummy word line. Although the stop layer 102 illustrated in FIG. 1 is a single-layered structure, the present invention is not limited thereto. In other embodiments, the stop layer 102 may also be a multi-layered structure. The multilayer structure may include a plurality of dielectric layers (e.g., silicon oxide layers) and a plurality of conductive layers (e.g., polysilicon layers) stacked alternately.

The stack structure 110 may be formed on the stop layer 102, so that the stop layer 102 is disposed between the buffer layer 100 and the stack structure 110. In an embodiment, the stack structure 110 may include a plurality of dielectric layers 112 and a plurality of sacrificial layers 114 stacked alternately. In an embodiment, the dielectric layers 112 and the sacrificial layers 114 may be different dielectric materials or materials with different etching rates. For example, the dielectric layers 112 may be silicon oxide layers; and the sacrificial layers 114 may be silicon nitride layers, polysilicon layers or metal tungsten layers. The number of the dielectric layers 112 and the sacrificial layers 114 may be adjusted by the needs, the invention is not limited thereto.

The cap layer 116 may be formed on the stack structure 110, so that the stack structure 110 is disposed between the stop layer 102 and the cap layer 116. In an embodiment, a material of the cap layer 116 includes a dielectric material, such as silicon oxide.

The vertical channel structure 130 may be formed in the stack structure 110 and the stop layer 102 in the first region R1. As shown in FIG. 1, the vertical channel structure 130 may penetrate through the stack structure 110, the stop layer 102, and partially extend into the buffer layer 100. It should be noted that when forming an opening 115 that may accommodate the vertical channel structure 130, the stop layer 102 may be used not only as an etching stop layer, but also to prevent arcing effects generated during the plasma etching, thereby improving the reliability of the device. In this embodiment, the stop layer 102 may be regarded as a discharging layer, which is usually grounded to the silicon substrate to reduce the charge accumulated by the said plasma etching, thereby avoiding damage to the device. Therefore, during the high aspect ratio etching process, the stop layer 102 is usually grounded to the silicon substrate to avoid arc discharge.

Basically, according to different forms of the 3D memory device, the vertical channel structure 130 may have different configurations, which are described in detail as follows.

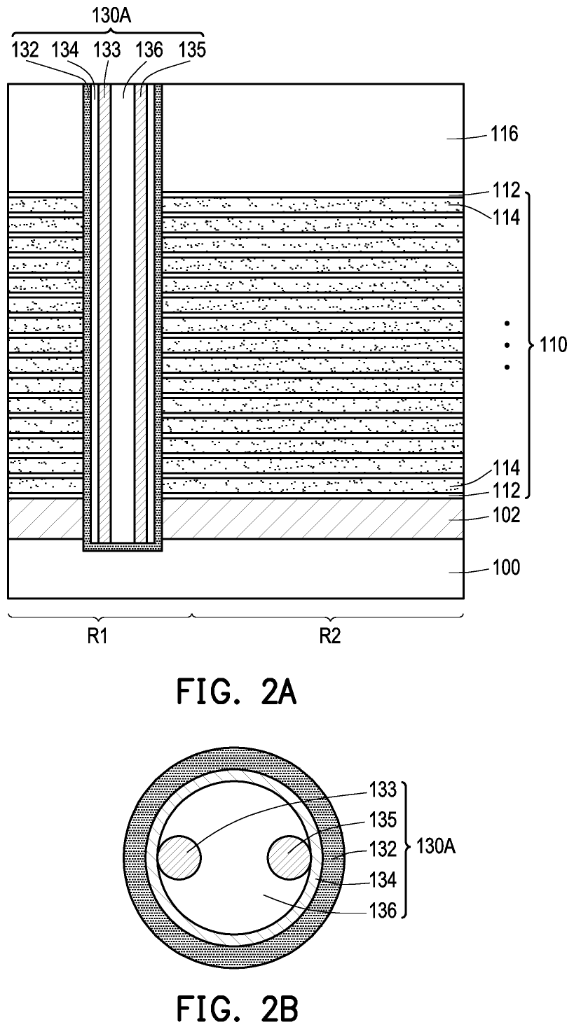

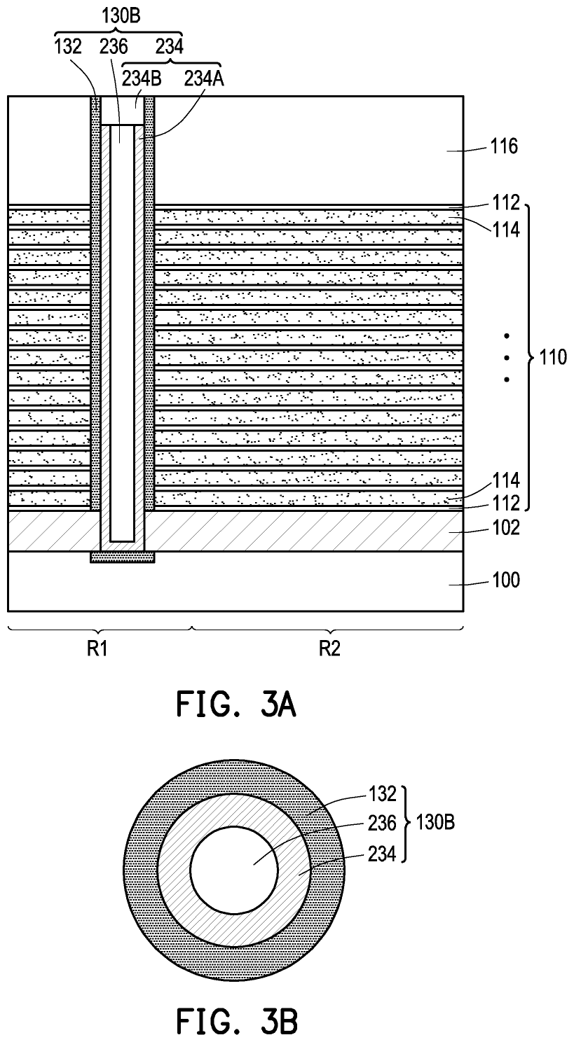

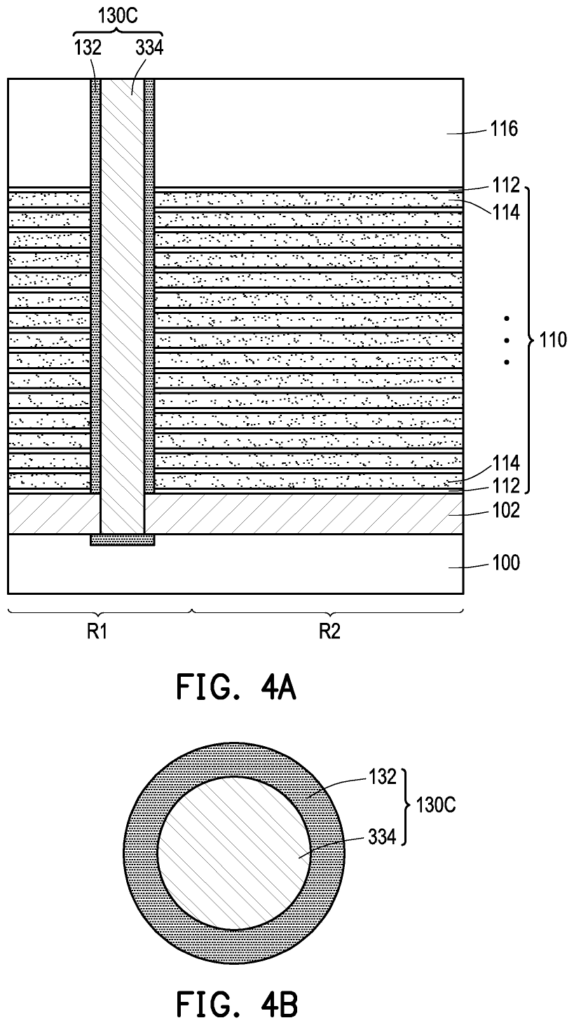

FIG. 2A, FIG. 3A, and FIG. 4A are schematic cross-sectional views illustrating a vertical channel structure according to various embodiments of the invention. FIG. 2B, FIG. 3B, and FIG. 4B are schematic plan views of FIG. 2A, FIG. 3A, and FIG. 4A, respectively.

Referring to FIG. 2A and FIG. 2B, when the 3D memory device is a 3D AND flash memory, the vertical channel structure 130A may include a charge storage structure 132, a channel layer 134, a dielectric material 136, a first source/drain (S/D) pillar 133, and a second S/D pillar 135. As shown in FIG. 2A, the first S/D pillar 133 and the second S/D pillar 135 may penetrate through the cap layer 116, the stack structure 110, and the stop layer 102, and partially extend into the buffer layer 100. In an embodiment, the first S/D pillar 133 and the second S/D pillar 135 may have the same conductive material, such as N-type doped (N+) polysilicon materials. The dielectric material 136 may disposed between the first S/D pillar 133 and the second S/D pillar 135 to separate the first S/D pillar 133 from the second S/D pillar 135. In addition, as shown in FIG. 2B, the channel layer 134 may laterally surround the dielectric material 136, the first S/D pillar 133 and the second S/D pillar 135. The first S/D pillar 133 and the second S/D pillar 135 physically contct a portion of the channel layer 134, respectively. The charge storage structure 132 may laterally surround the channel layer 134. In an embodiment, the charge storage structure 132 may be a composite layer of a tunneling layer, a charge storage layer and a block layer. The tunneling layer, the charge storage layer and the block layer may refer to oxide/nitride/oxide (ONO), respectively. In another embodiment, the tunneling layer may be a composite layer of oxide/nitride/oxide/ (ONO). In the other embodiment, the block layer may be a composite layer of oxide/nitride/oxide (ONO), or other suitable materials. The channel layer 134 may include a doped polysilicon layer or an undoped polysilicon layer. The dielectric material 136 may include silicon oxide, silicon nitride, silicon oxynitride, or a combination thereof.

Referring to FIG. 3A and FIG. 3B, when the 3D memory device is a first type of a 3D NAND flash memory, the vertical channel structure 130B may include a charge storage structure 132, a channel structure 234, and a dielectric pillar 236. As shown in FIG. 3A, the dielectric pillar 236 may penetrate through the cap layer 116, the stack structure 110, and the stop layer 102, and partially extend into the buffer layer 100. The channel structure 234 may include a liner 234A and a plug 234B. The liner 234A may cover the sidewall and the bottom surface of the dielectric pillar 236, and the plug 234B may seal the top surface of the dielectric pillar 236. In this case, the channel structure 234 may completely wrap all surfaces of the dielectric pillar 236. The charge storage structure 132 may be disposed between the channel structure 234 and the cap layer 116, and between the channel structure 234 and the stack structure 110. The charge storage structure 132 between the channel structure 234 and the stop layer 102 is removed. The channel structure 234 directly contacts the stop layer 102. From the perspective of the cross-sectional view of FIG. 3B, the charge storage structure 132 may laterally surround the channel structure 234. The materials of the charge storage structure 132, the channel structure 234 and the dielectric pillar 236 are respectively the same as the charge storage structure 132, the channel layer 134 and dielectric material 136 described in previous paragraphs.

Referring to FIG. 4A and FIG. 4B, when the 3D memory device is a second type of a 3D NAND flash memory, the vertical channel structure 130C may include a charge storage structure 132 and a channel pillar 334. As shown in FIG. 4A, the channel pillar 334 may penetrate through the cap layer 116, the stack structure 110, and the stop layer 102, and partially extend into the buffer layer 100. The charge storage structure 132 may be disposed between the channel pillar 334 and the cap layer 116, between the channel pillar 334 and the stack structure 110. From the perspective of the cross-sectional view of FIG. 4B, the charge storage structure 132 may laterally surround the channel pillar 334. The charge storage structure 132 between the channel pillar 334 and the stop layer 102 is removed. The channel pillar 334 directly contacts the stop layer 102. The materials of the charge storage structure 132 and the channel pillar 334 are respectively the same as the charge storage structure 132 and the channel layer 134 described in previous paragraphs.

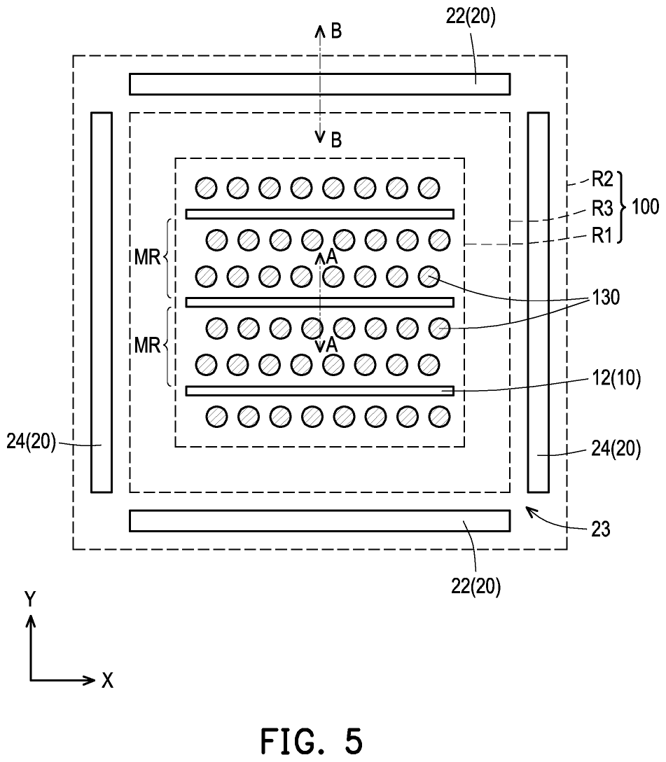

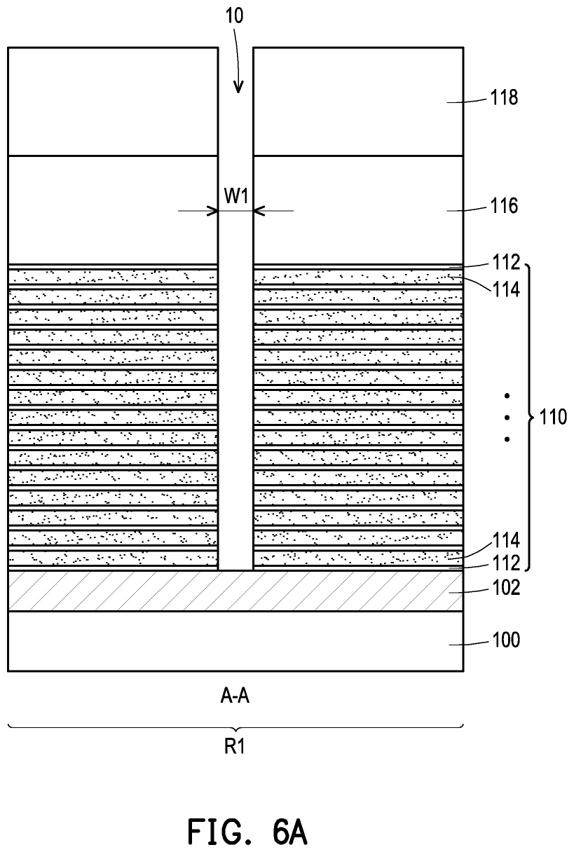

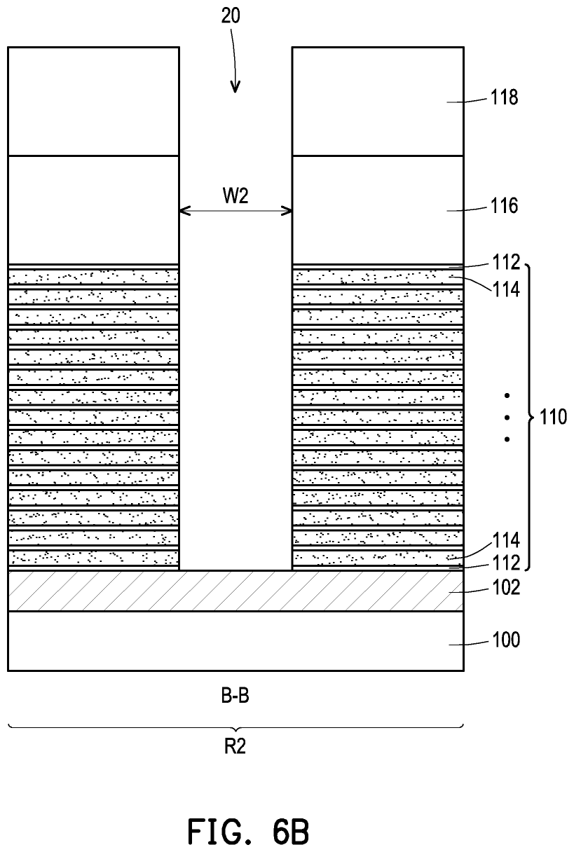

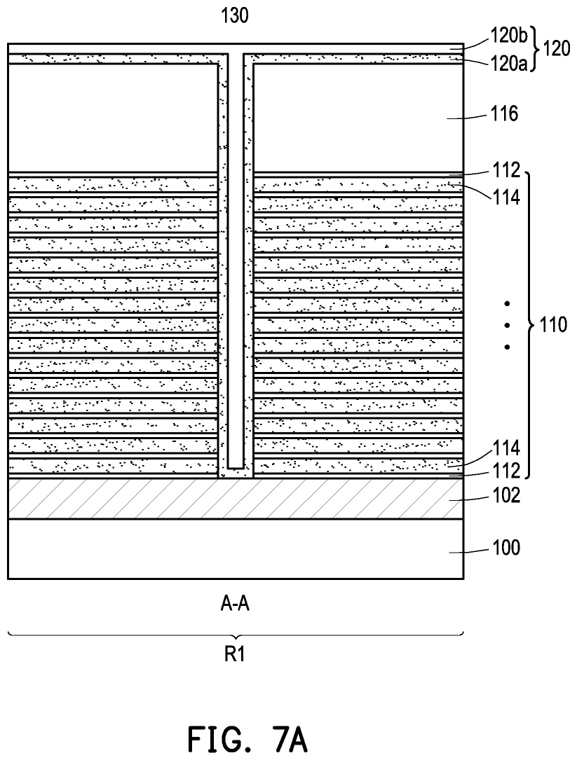

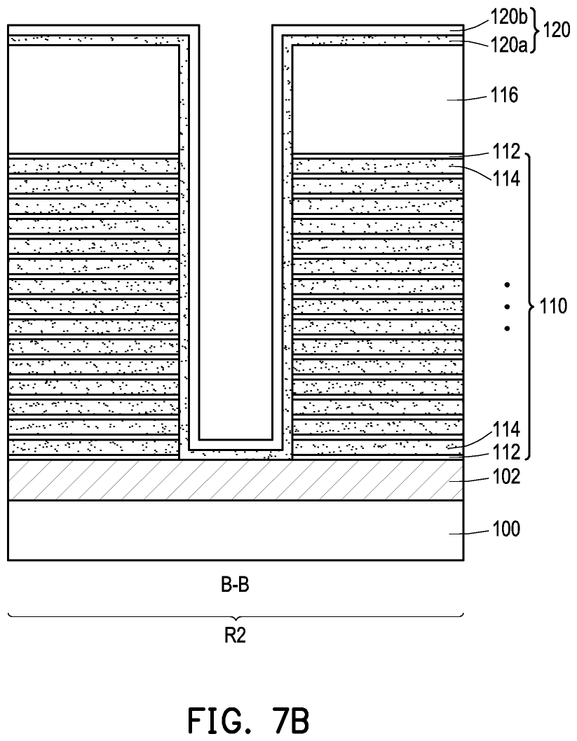

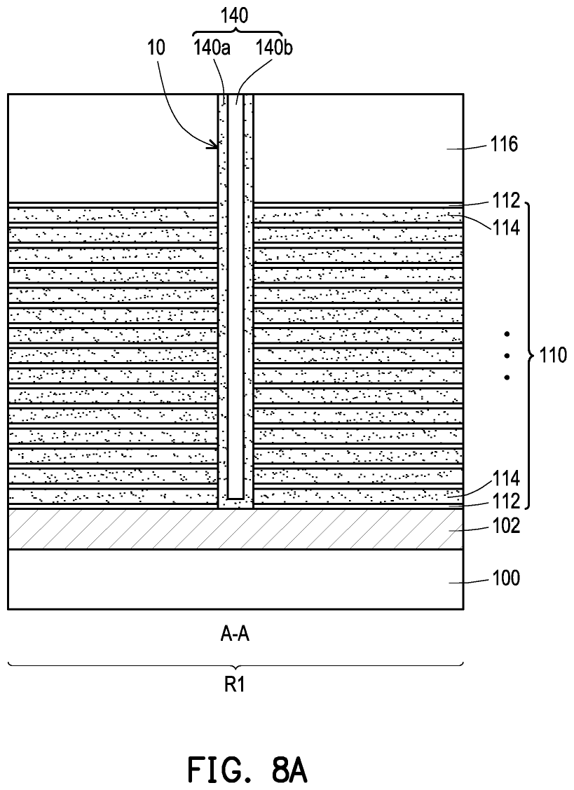

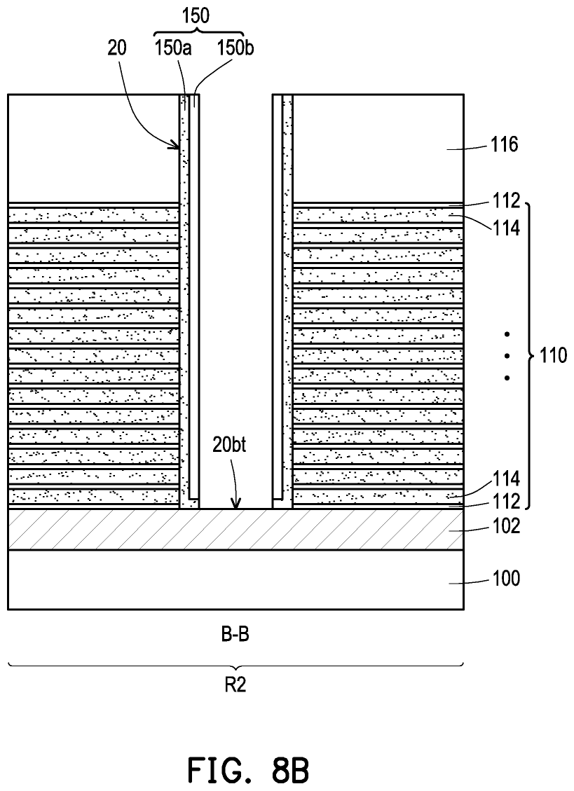

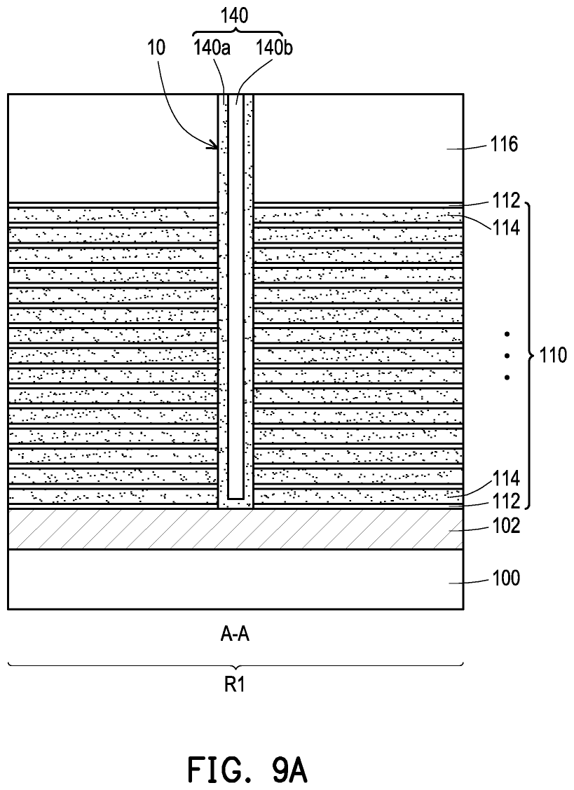

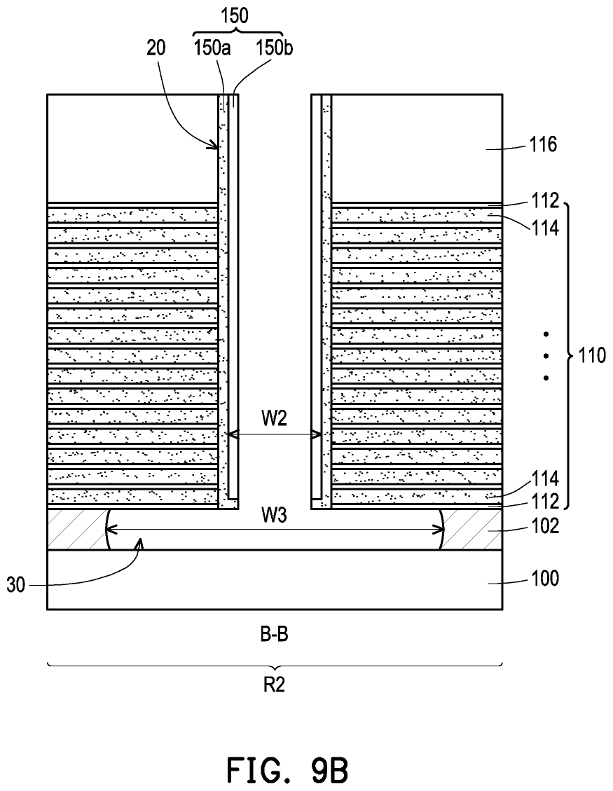

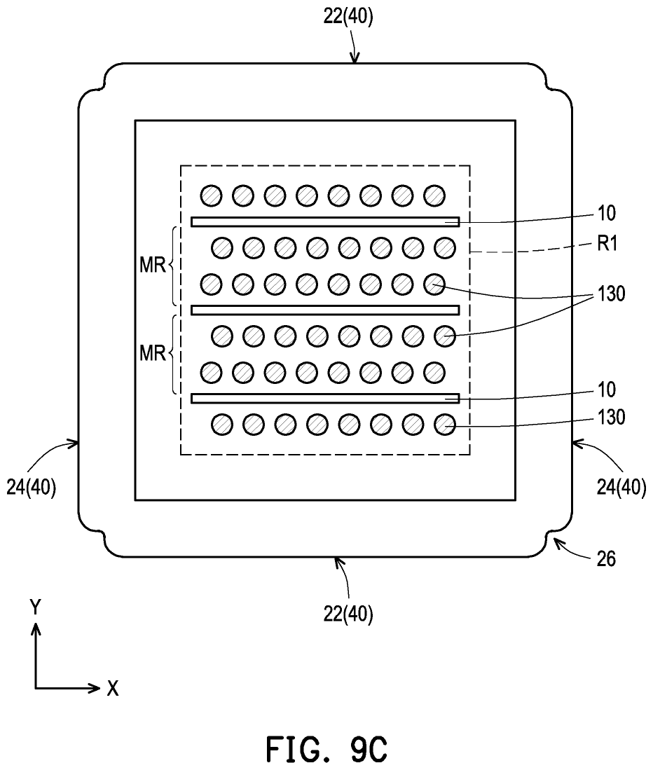

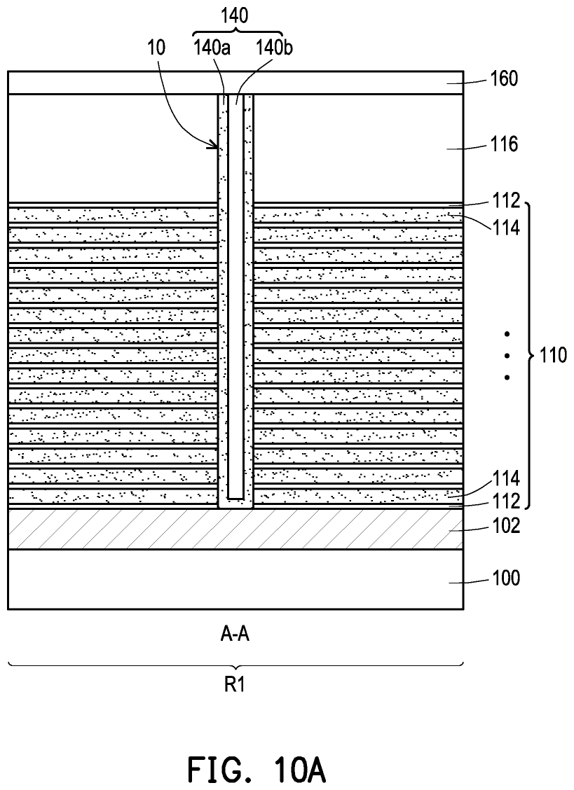

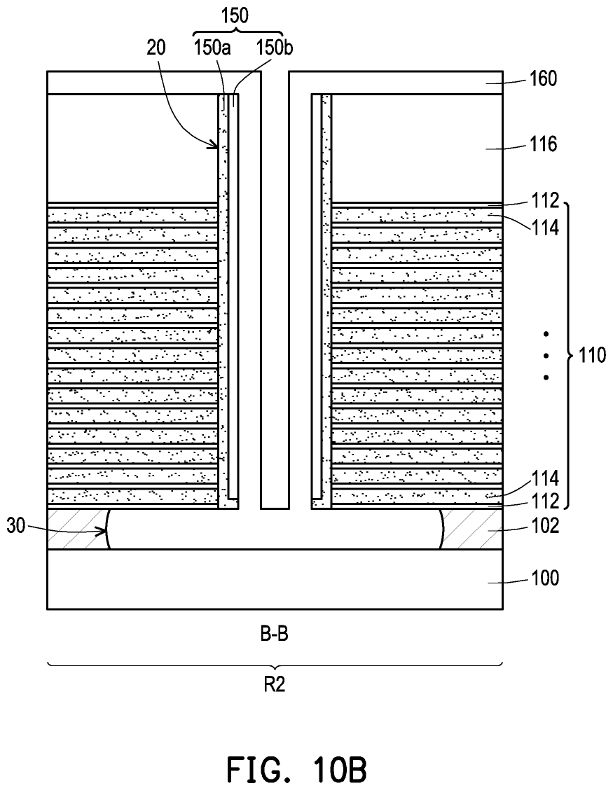

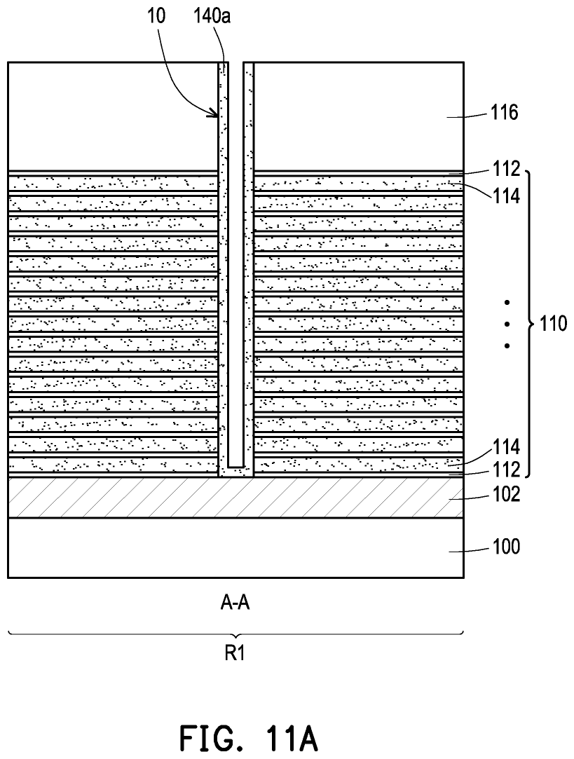

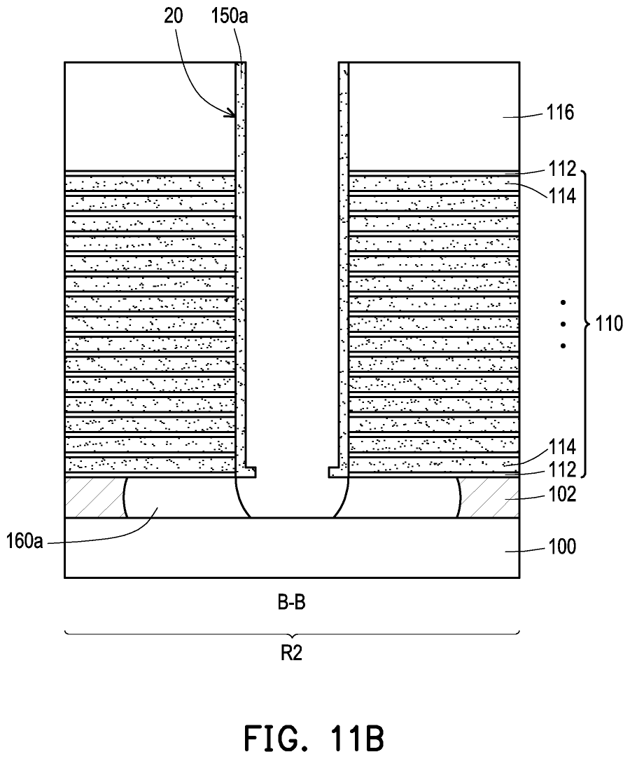

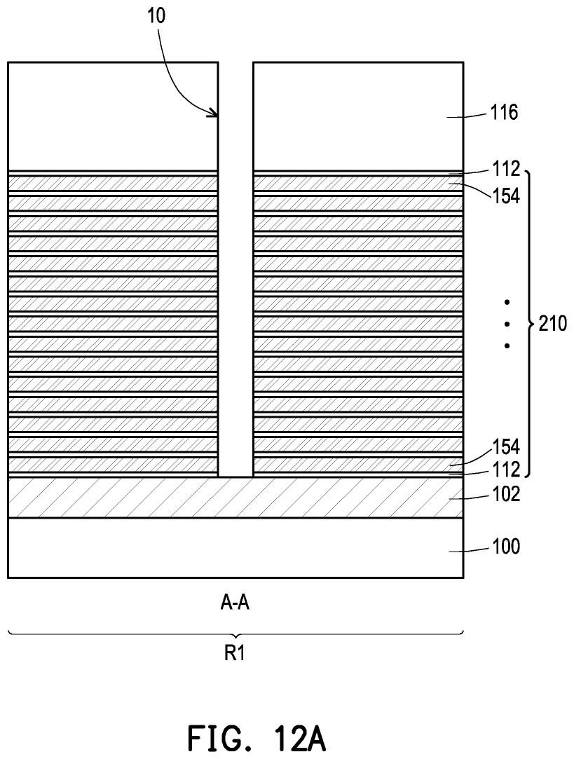

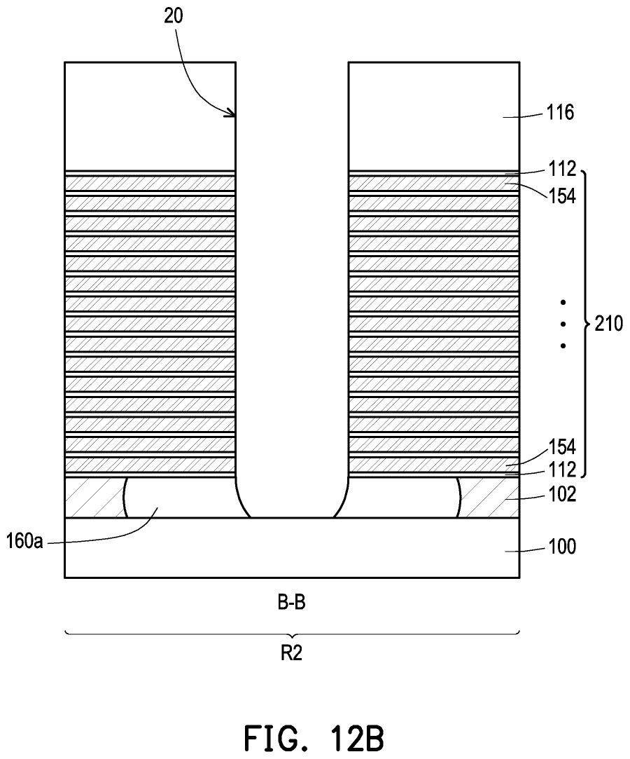

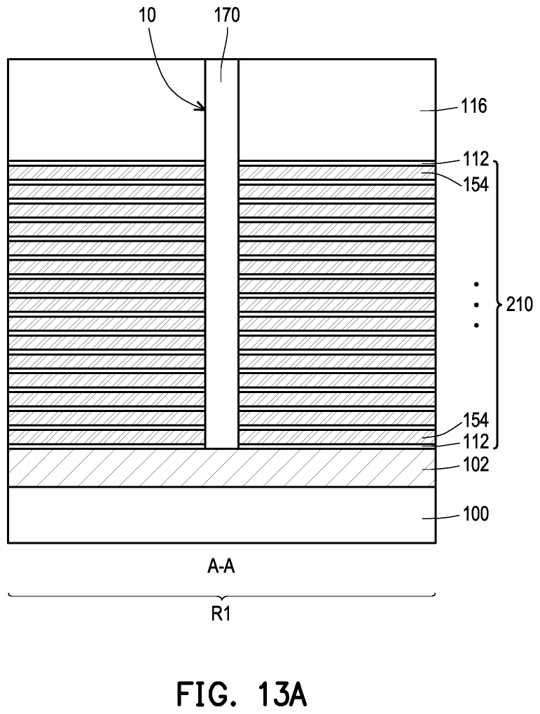

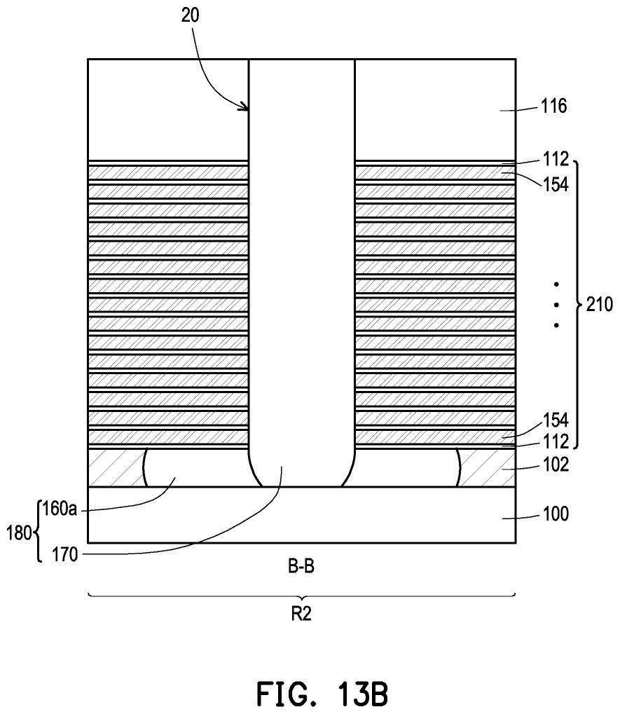

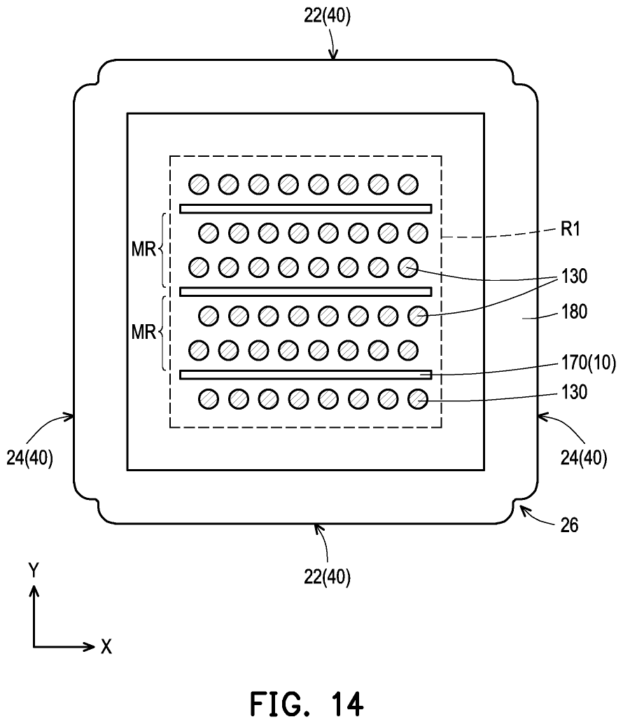

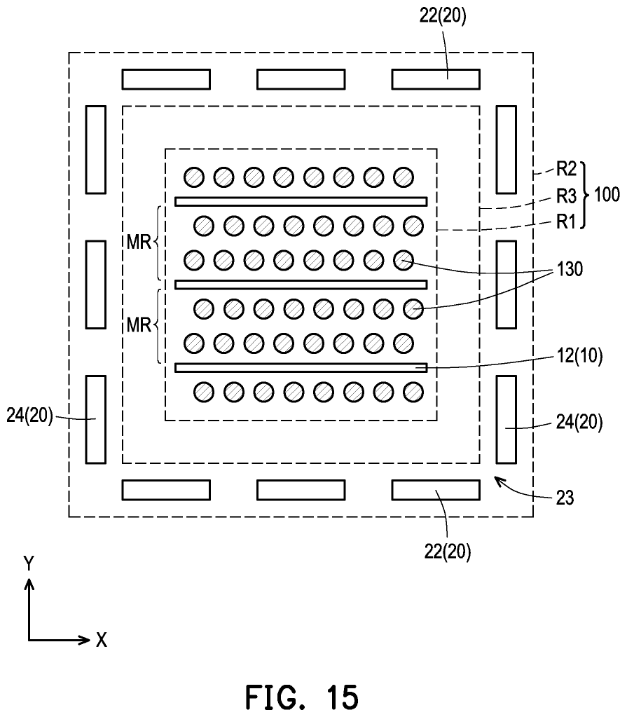

FIG. 5 is a schematic plan view of a 3D memory device according to an embodiment of the invention. FIG. 6A, FIG. 7A, FIG. 8A, FIG. 9A, FIG. 10A, FIG. 11A, FIG. 12A, and FIG. 13A are schematic cross-sectional views of a manufacturing process along a line A-A of FIG. 5. FIG. 6B, FIG. 7B, FIG. 8B, FIG. 9B, FIG. 10B, FIG. 11B, FIG. 12B, and FIG. 13B are schematic cross-sectional views of a manufacturing process along a line B-B of FIG. 5. FIG. 14 is a schematic plan view of a 3D memory device according to another embodiment of the invention. FIG. 15 is a schematic plan view of a 3D memory device according to alternative embodiments of the invention.

After the vertical channel structure 130 of FIG. 1 is formed, a gate replacement process may be performed to replace the sacrificial layers 114 of the stack structure 110 by a plurality of conductive layers 154, as shown in FIG. 5 to FIG. 14.

First, referring to FIG. 5, the buffer layer 100 may include a first region R1, a second region R2, and a third region R3. The second region R2 may surround the first region R1, and the third region R3 may be disposed between the first region R1 and the second region R2. In an embodiment, the first region R1 may be an array region, the second region R2 may be an isolation ring region, and the third region R3 may be a staircase region. For the sake of clarity, the subsequent cross-sectional views of FIG. 6A to FIG. 13A only illustrate the line A-A in the first region R1, and the subsequent cross-sectional views of FIG. 6B to FIG. 13B only illustrate the line B-B in the second region R2, and the vertical channel structure 130 is omitted.

As shown in FIG. 6A and FIG. 6B, after the vertical channel structure 130 is formed, a first opening 10 may be formed in the stack structure 100 in the first region R1, and a second opening 20 may be formed in the stack structure 100 in the second region R2. A method of forming the first opening 10 and the second opening 20 may include: forming a mask pattern 118 on the cap layer 116; performing a plasma etching process to remove a portion of the cap layer 116 and a portion of the stack structure 110 by using the mask pattern 118 as a mask, thereby exposing a portion of a surface of the stop layer 102. In an embodiment, the second opening 20 has a width W2 greater than a width W1 of the first opening 10. A ratio of the width W2 of the second opening 20 to the width W1 of the first opening 10 is greater than or equal to 2. For example, the width W1 of the first opening 10 is about 100 nm, and the width W2 of the second opening 20 is about 300 nm.

Specifically, as shown in FIG. 5, the second opening 20 may include two first trenches 22 (may be referred to as first slits) extending along a X direction and two second trenches 24 (may be referred to as second slits) extending along a Y direction. The first trenches 22 and the second trenches 24 are separated from each other and not connected to each other, thereby forming an unclosed slit ring structure. That is, there is a break 23 between the adjacent first trench 22 and the second trench 24. It should be noted that, after the first opening 10 and the second opening 20 are formed, the stop layer 102 may still extend continuously between the array regions R1. Specifically, the stop layer 102 is located below the stack structure 110, and the first opening 10 and the second opening 20 only expose a portion of the surface of the stop layer 102 without extending into the buffer layer 100. In other words, the stop layer 102 has not been cut off by the first opening 10 and/or the second opening 20. Therefore, the stop layer 102 may be grounded to the silicon substrate in the subsequent high aspect ratio etching process to avoid the arcing effect. On the other hand, the first opening 10 may include a plurality of third trenches 12 (may be referred to as third slits) extending along the X direction to divide the plurality of vertical channel structures 130 into a plurality of memory cell regions MR arranged along the Y direction.

Although the first trenches 22 and the second trenches 24 shown in FIG. 5 are continuous trench or slit structures, the present invention is not limited thereto. In other embodiments, the first trenches 22 and the second trenches 24 may also be discontinuous trench or slit structures, as shown in FIG. 15.

Next, referring to FIG. 7A and FIG. 7B, a dielectric material 120 is formed to fill in the first opening 10 and the second opening 20. Specifically, the dielectric material 120 includes a first material 120a and a second material 120b. The first material 120a conformally covers the surface of the first opening 10 and extends to cover the top surface of the cap layer 116, and the second material 120b conformally covers the first material 120a, as shown in FIG. 7A. The first material 120a also conformally covers the surface of the second opening 20 and extends to cover the top surface of the cap layer 116, and the second material 120b conformally covers the first material 120a, as shown in FIG. 7B. In an embodiment, the first material 120a and the sacrificial layers 114 have the same material, and the first material 120a and the second material 120b have different materials. For example, the material of the first material 120a and the sacrificial layer 114 may be silicon nitride, and the second material 120b may be silicon oxide. In the embodiment, the dielectric material 120 is formed by a deposition method with the high sidewall step coverage, such as a chemical vapor deposition (CVD) method, an atomic layer deposition (ALD) method, or a combination thereof.

It should be noted that, in the present embodiment, the width W1 of the first opening 10 is less than the width W2 of the second opening 20. Accordingly, after the dielectric material 120 is formed, the dielectric material 120 fills up the first opening 10, but not fill up the second opening 20. In this case, the dielectric material 120 on the second opening 20 forms a recess opening 25.

Referring to FIG. 7A to FIG. 8A and FIG. 7B to FIG. 8B, a first etching process is performed to remove a portion of the dielectric material 120 on the top surface of the cap layer 116 (or the stack structure 110) and on the bottom surface 20bt of the second opening 20, so as to form a first dielectric layer 140 in the first opening 10 and a second dielectric layer 150 (may be referred to as an insulating layer) on the sidewall of the second opening 20. Specifically, the first dielectric layer 140 may include a first material layer 140a and a second material layer 140b. The second material layer 140b may penetrate through the cap layer 116 and the stack structure 110, and the first material layer 140a wraps the second material layer 140b and is in contact with the stack structure 110 and the stop layer 102, as shown in FIG. 8A. In addition, the second dielectric layer 150 may include a first material layer 150a and a second material layer 150b. The first material layer 150a covers the sidewall of the cap layer 116 and the sidewall of the stack structure 110, and the second material layer 150b is disposed on the first material layer 150a, as shown in FIG. 8B. It should be noted that, in the present embodiment, while the first dielectric layer 140 seals the first opening 10, the second dielectric layer 150 exposes a portion of the stop layer 102 at the bottom surface 20bt of the second opening 20. In an embodiment, the first etching process includes a blanket etching process. In alternative embodiments, the first etching process includes a dry etching process, a wet etching process, an isotropic etching process, an anisotropic etching process, or a combination thereof.

Referring to FIG. 8A to FIG. 9A and FIG. 8B to FIG. 9B, a second etching process is performed by using the first dielectric layer 140 and the second dielectric layer 150 as a mask to remove the stop layer 102 exposed at the bottom surface 20bt of the second opening 20, thereby forming a cavity 30. As shown in FIG. 9B, the cavity 30 laterally extends below the stack structure 110, so that a width W3 of the cavity 30 is greater than the width W2 of the second opening 20. In an embodiment, the second etching process includes a dry etching process, a wet etching process, a chemical dry etching (CDE) process, or a combination of an oxidation process and a wet cleaning process. For example, the wet etching process of the HNA system which includes an etchant of HNO₃/HF/H₂O₂ may be performed by using the first material layers 140a, 150a (e.g., silicon nitride) as an etching stop layer to remove the second material layers 140b, 150b (e.g., silicon oxide) and a portion of the stop layer 102 (e.g., polysilicon). On the other hand, the wet etching process of the Alkali Hydroxide system which includes an etchant of NaOH or KOH may also be performed by using the second material layer 140b, 150b (e.g., silicon oxide) or the first material layers 140a, 150a (e.g., silicon nitride) as an etching stop layer to remove a portion of the stop layer 102 (e.g., polysilicon). In this embodiment, the second material layers 140b, 150b still remain in the first opening 10 and the second opening 20, as shown in FIG. 9A and FIG. 9B. Further, a chemical dry etching (CDE) process with high selectivity may also be used to remove a portion of the stop layer 102.

It should be noted that after performing the second etching process, the cavity 30 may be connected to the two first trenches 22 and the two second trenches 24, thereby forming a ring-shaped opening 40, as shown in the top view of FIG. 9C. In other words, the cavity 30 may extend from the ends of the first trenches 22 and/or the ends of the second trenches 24 to the break 23 (as shown in FIG. 5) to connect the first trenches 22 and the second trenches 24. In this case, the stop layer 102 is cut off by the ring-shaped opening 40, so that the stop layer 102 in the first region R1 is electrically isolated from the stop layer 102 in the outer region. In the present embodiment, since there is no high aspect ratio etching process required to be grounded to avoid the arcing effect after forming the first opening 10 and the second opening 20, the stop layer 102 can be cut off or divided at this step to avoid the adjacent stop layers 102 between adjacent regions are electrically connected to each other, thereby affecting the operation of the memory device. In addition, since the cavity 30 extends from the ends of the first trenches 22 and/or the second trenches 24, the connection point 26 of the first trenches 22 and the second trenches 24 may have an arc profile, as shown in FIG. 9C.

Next, a filling material 160 is formed. As shown in FIG. 10A, the filling material 160 covers the cap layer 116 and the first dielectric layer 140. On the other hand, as shown in FIG. 10B, the filling material 160 extends from the top surface of the cap layer 116 into the second opening 20 and fills in the cavity 30. In an embodiment, the filling material 160 includes silicon oxide, silicon nitride, silicon oxynitride, or the like, which is used to replace the hollowed-out stop layer 102 to support the entire stack structure 110.

Referring to FIG. 10A to FIG. 11A and FIG. 10B to FIG. 11B, a wet etching process is performed to remove a portion of the filling material 160 and the second material layers 140b, 150b. In this case, as shown in FIG. 11A, the first material layer 140a still covers the sidewall and bottom surface of the first opening 10, and an outer surface of the first material layer 140a is exposed. On the other hand, as shown in FIG. 11B, the second opening 20 extends downward into the filling material 160a, and an outer surface of the first material layer 150a and an outer surface of the filling material 160a are exposed.

Referring to FIG. 11A to FIG. 12A and FIG. 11B to FIG. 12B, an etching process is performed through the first opening 10 and the second opening 20 to remove the first material layers 140a and 150a and the sacrificial layers 114 to form a plurality of gaps (not shown) between the dielectric layers 112. In an embodiment, the etching process may be a wet etching process. For example, when the first material layers 140a, 150a and the sacrificial layers 114 are silicon nitride, the etching process may be to use an etching solution containing phosphoric acid, and pour the etching solution into the first opening 10 and the second opening 20, thereby removing the first material layers 140a, 150a and the sacrificial layers 114. Since the etching solution has high etching selectivity with respect to the first material layers 140a, 150a and the sacrificial layers 114, the first material layers 140a, 150a and the sacrificial layers 114 may be completely removed, while the dielectric layers 112, the stop layer 102 and the cap layer 116 are not removed or only a small amount of those are removed.

Afterward, a plurality of conductive layers 154 are formed in the said gaps, thereby accomplishing the 3D memory device of the present invention. In an embodiment, a material of the conductive layers 154 is, for example, polysilicon, amorphous silicon, tungsten (W), cobalt (Co), aluminum (Al), tungsten silicide (WSiₓ), or cobalt silicide (CoSiₓ). In addition, before forming the conductive layers 154, a buffer layer and a barrier layer may be sequentially formed between the dielectric layers 112 and the conductive layers 154. A material of the buffer layer is made of, for example, a material with a high dielectric constant of a dielectric constant greater than 7, such as aluminum oxide (Al₂O₃), hafnium oxide (HfO₂), lanthanum oxide (La₂O₅), transition metal oxide, lanthanide oxide, or a combination thereof. A material of the barrier layer is made of, for example, titanium (Ti), titanium nitride (TiN), tantalum (Ta), tantalum nitride (TaN), or a combination thereof.

In the present embodiment, the 3D memory device has a plurality of memory cells (not shown). The number of the memory cells may be adjusted with the number of the conductive layers 154 in the stack structure 210, the present invention is not limited thereto.

Referring to FIG. 13A and FIG. 13B, after the gate replacement process is performed, an isolation material 170 may be formed in the first opening 10 and the second opening 20 (or the ring-shaped opening 40). In an embodiment, the isolation material 170 and the filling material 160a may have the same material, such as silicon oxide. In this case, the isolation material 170 may contact the filling material 160a to form an isolation ring structure 180, as shown in FIG. 14 and FIG. 13B.

In alternative embodiments, the method of forming the isolation ring structure 180 may also include: forming a liner layer (e.g., silicon oxide) to conformally cover the surfaces of the first opening 10 and the second opening 20 (or the ring-shaped opening 40); removing a portion of the liner layer at the bottom surfaces of the first opening 10 and the second opening 20; and forming a metal layer (e.g., W) in the first opening 10 and the second opening 20 so that the metal layer contacts the stop layer 102.

In summary, in the present embodiment, a first opening and a second opening are formed in the array region and the isolation ring region simultaneously, so that the gate replacement process may be performed through the first and the second openings. The second opening may include an unclosed slit ring structure to prevent the discharge layer from being cut off by the second opening, thereby preventing the arcing effect. In addition, in the present embodiment, a subsequent etching process may be performed to remove the discharge layer exposed at the bottom surface of the second opening, thereby forming a cavity. The cavity may laterally penetrate through the unclosed slit ring structure to form a ring-shaped opening, thereby electrically or physically separating the discharge layer in the array region from the discharge layer in the outer region. In this case, the present embodiment can avoid the arcing effect while cutting the discharge layer, thereby improving the reliability of the 3D memory device.

Although the invention has been described with reference to the above embodiments, it will be apparent to one of ordinary skill in the art that modifications to the described embodiments may be made without departing from the spirit of the invention. Accordingly, the scope of the invention is defined by the attached claims not by the above detailed descriptions.

What is claimed is:

1. A method of forming a three-dimensional (3D) memory device, comprising:
providing a buffer layer having a first region and a second region, wherein the second region surrounds the first region;
forming a stop layer and a stack structure comprising a plurality of dielectric layers and a plurality of sacrificial layers stacked alternately on the buffer layer, wherein the stack structure comprises at least one vertical channel structure penetrating through the stack structure in the first region;
forming a first opening in the stack structure in the first region, and forming a second opening in the stack structure in the second region, wherein the second opening has a width greater than a width of the first opening;
forming a dielectric material to fill in the first and second openings;
performing a first etching process to remove at least a portion of the dielectric material on a bottom surface of the second opening to expose a portion of the stop layer, thereby forming a first dielectric layer in the first opening and forming a second dielectric layer on a sidewall of the second opening; and
performing a second etching process to remove the stop layer exposed at the bottom surface of the second opening, thereby forming a cavity extending laterally below the stack structure, so that the cavity is connected to the second opening to form a closed ring.

2. The method according to claim 1, wherein the first dielectric layer covers a bottom surface of the first opening, while the second dielectric layer exposes the stop layer at the bottom surface of the second opening.

3. The method according to claim 1, wherein the first region comprises an array region, and the second region comprises an isolation ring region.

4. The method according to claim 3, wherein the second opening comprises two first trenches extending along a X direction and two second trenches extending along a Y direction, and the two first trenches and the two second trenches are separated from each other.

5. The method according to claim 4, wherein the cavity is connected to the two first trenches and the two second trenches to form the closed ring after performing the second etching process.

6. The method according to claim 1, wherein the first opening comprises a plurality of third trenches extending along a X direction to divide the plurality of vertical channel structures into a plurality of memory cell region arranged along a Y direction.

7. The method according to claim 1, wherein after forming the closed ring, the method further comprises forming a filling material to fill in the cavity.

8. The method according to claim 7, wherein the dielectric material comprises a first material and a second material, the first material covers a surface of the first opening and a surface of the second opening, the second material covers the first material, the first material and the plurality of sacrificial layers have the same material, and the first material and the second material have different materials.

9. The method according to claim 8, wherein after forming the filling material, the method further comprises:
removing the second material to expose the first material;
performing a gate replacement process through the first and second openings to replace the plurality of sacrificial layers by a plurality of conductive layers; and
forming an isolation material to fill in the first and second openings.

10. The method according to claim 8, wherein a material of the stop layer comprises a conductive material.

11. The method according to claim 1, wherein a ratio of the width of the second opening to the width of the first opening is greater than or equal to 2.

12. The method according to claim 1, wherein the first etching process comprises a blanket etching process.

13. The method according to claim 1, wherein the second etching process comprises a dry etching process, a wet etching process, a chemical dry etching process, or a combination of an oxidation process and a wet cleaning process.

14. A method of forming a three-dimensional (3D) memory device, comprising:
forming a discharging layer and a stack structure on a buffer layer, wherein the stack structure comprises a plurality of dielectric layers and a plurality of sacrificial layers stacked alternately;
forming a plurality of vertical channel structures in the stack structure;
forming an opening in the stack structure, wherein the opening includes two first trenches extending along a X direction and two second trenches extending along a Y direction, and the two first trenches and the two second trenches are separated from each other;
forming an insulating layer on a sidewall of the opening, wherein the insulating layer exposes the discharging layer at a bottom surface of the opening;
removing the discharging layer exposed at the bottom surface of the opening to form a cavity, wherein the cavity extends below the stack structure to connect the two first trenches and the two second trenches, thereby forming a ring-shaped opening;
performing a gate replacement process to replace the plurality of sacrificial layers of the stack structure by a plurality of conductive layers, wherein the plurality of conductive layers respectively surround the plurality of vertical channel structures to form a plurality of memory cells; and
filling an isolation material in the ring-shaped opening to form an isolation ring structure.

15. The method according to claim 14, wherein each first trench comprises a continuous slit structure or a discontinuous slit structure.

16. The method according to claim 14, wherein each second trench comprises a continuous slit structure or a discontinuous slit structure.

17. The method according to claim 14, wherein a material of the discharging layer comprises a conductive material, the conductive material comprises a semiconductor material comprising polysilicon, III-V compound semiconductor, or a combination thereof.

18. The method according to claim 14, wherein the discharging layer comprises a single-layered structure or a multi-layered structure.

19. The method according to claim 18, wherein the multi-layered structure comprises a plurality of dielectric layers and a plurality of conductive layers stacked alternately.

20. The method according to claim 14, wherein a material of the plurality of sacrificial layers comprises silicon nitride, polysilicon, tungsten, or a combination thereof.
